(19) United States
(12) Patent Application Publication
(10) Pub. No.: US 2009/0163043 A1
(43) Pub. Date: Jun. 25, 2009

(54) PATCH PANEL WITH ANGLED MODULE

(76) Inventors: YANNICK DEMERS, St-Jean-sur-Richelieu (CA); LUC MILETTE, Montreal (CA)

Correspondence Address: GOUDREAU GAGE DUBUC, 2000 MCGILL COLLEGE, SUITE 2200, MONTREAL, QC, H3A 3H3, CA

(21) Appl. No.: 12/341,168

(22) Filed: Dec. 22, 2008

Related U.S. Application Data
(60) Provisional application No. 61/015,692, filed on Dec. 21, 2007.

(51) Int. Cl. H01R 29/00; H01R 13/60; H05K 13/04

(52) U.S. Cl. 439/43; 439/540.1; 29/729

(57) ABSTRACT

A patch panel with angled connector modules for mounting to a telecommunications rack comprising a frame comprising a flat elongate frame member having an opening formed therein for mounting one of the connector module. The outer vertical surfaces of each connector module are outwardly angled relative to one another to form a generally V-shape when viewed from above. The modules are reversible and two modules can therefore be mounted to the frame member with a reversed left-to-right orientation. A pattern of modules can thus be created on a single frame as well as along the length of the rack by stacking a plurality of frames one on top of the other. In particular, two modules can be mounted such that their outer vertical surfaces are either substantially parallel or intersect at an angle.

### CROSS REFERENCE TO RELATED APPLICATIONS

This application claims priority on U.S. Provisional Application No. 61/015,692, filed on Dec. 21, 2007 and which is herein incorporated by reference in its entirety.

### FIELD OF THE INVENTION

The present invention relates to a patch panel with angled modules. In particular, the patch panel comprises a planar frame on which reversible angled modules are detachably mounted.

### BACKGROUND OF THE INVENTION

As known in the art, a major drawback of conventional flat patch panels, besides the fact that the rear of the panel is difficult to reach, is that they require additional space for horizontal cable managers, resulting in lower port density for cable connections. This is incompatible with the limited space in telecommunication closets, which leads to a need for patch panels that can accommodate more cables to maintain high-density. Also, as higher frequencies are used, falling below a minimum cable bend radius may affect signal transmission performance as well as damage cables and it thus becomes advantageous to control the cable bend radius better than with conventional patch panels.

To solve these problems, the prior art teaches a plurality of angled patch panel assemblies, which, due to their unique geometry, have the advantage of being space efficient while solving problems associated with the control of the cable bend radius. Typically, such patch panels comprise an angled frame mounted to a telecommunication rack and comprising a plurality of apertures for receiving connector modules. However, one drawback with these patch panels is that they are at a fixed angle and are generally fixedly mounted along the width of the rack. As a result, there is only provided limited flexibility and access to the cables, thus making cable management more difficult. Other angled patch panel assemblies use a standard flat patch panel frame having angled connector modules mounted thereon. In some embodiments, the modules are allowed to rotate relative to the frame to ease access to rear cable connections. However, these patch panel assemblies typically do not provide for an increased number of possible cable connections relative to the planar patch panel surface, thus not fully overcoming the need for high-density connections.

What is therefore needed, and an object of the present invention, is an improved patch panel with angled modules, which allows high-density cable management.

### SUMMARY OF THE INVENTION

More specifically, in accordance with the present invention, there is provided a patch panel for mounting to a telecommunications rack comprising a pair of spaced vertical rails. The patch panel comprises a frame adapted for attachment between the rails and comprising a substantially flat elongate frame member spanning a first vertical plane and having a pair of openings therein, and a connector module mounted in front of the elongate frame member to the frame member opening. The module comprises a face spanning a second vertical plane and a plurality of plug receiving receptacles spaced horizontally along a front surface of the face. The second plane intersects the first plane at a first acute angle and a left-to-right orientation of the module relative to the frame member opening is reversible.

In accordance with the present invention, there is also provided a connector module for mounting to a patch panel comprising a frame comprising a substantially elongate frame member spanning a first vertical plane, the frame member comprising an opening for receiving the connector module therein. The connector module comprises a face spanning a second vertical plane and a plurality of plug receiving receptacles spaced horizontally along the face. When the connector module is mounted in front of the elongate frame member to the frame member opening, the second plane intersects the first plane at a first acute angle and a left-to-right orientation of the module relative to the frame member opening is reversible.

Still in accordance with the present invention, there is also provided a method for mounting a patch panel to a telecommunications rack comprising a pair of spaced vertical rails. The method comprises providing a frame comprising a substantially flat elongate frame member spanning a first vertical plane and having an opening therein, attaching the frame to the rails, providing a connector module comprising a face spanning a second vertical plane and a plurality of plug receiving receptacles spaced horizontally along the face and mounting the module in front of the elongate frame member to the frame member opening. The second plane intersects the first plane at a first acute angle and a left-to-right orientation of the module relative to the frame member opening is reversible.

Other objects, advantages and features of the present invention will become more apparent upon reading of the following non-restrictive description of specific embodiments thereof, given by way of example only with reference to the accompanying drawings.

### BRIEF DESCRIPTION OF THE DRAWINGS

In the appended drawings:

FIG. 1 is a right front perspective view of a patch panel with angled modules mounted on a telecommunications rack in accordance with an illustrative embodiment of the present invention;

FIG. 2a is a right front perspective view of angled modules mounted to a patch panel frame in accordance with an illustrative embodiment of the present invention;

FIG. 2b is a right front perspective view of an angled module being installed on a patch panel frame in accordance with an illustrative embodiment of the present invention;

FIG. 2c is a rear perspective view of angled modules mounted to a patch panel frame in accordance with an illustrative embodiment of the present invention;

FIG. 3 is a top plan view of a patch panel with angled modules in accordance with an illustrative embodiment of the present invention;

FIG. 4a is a front perspective view of an angled connector module in accordance with an illustrative embodiment of the present invention;

FIG. 4b is a rear perspective view of an angled connector module in accordance with an illustrative embodiment of the present invention;

FIG. 4c shows top plan views of an angled connector module in accordance with alternative illustrative embodiments of the present invention;

FIG. 5a is a right front perspective view of a patch panel with angled modules mounted on a telecommunications rack in accordance with another alternative illustrative embodiment of the present invention; and

FIG. 5b is a top plan view of a patch panel with angled modules mounted on a telecommunications rack in accordance with another alternative illustrative embodiment of the present invention.

### DESCRIPTION OF ILLUSTRATIVE EMBODIMENTS

The present invention is illustrated in further details by the following non-limiting examples.

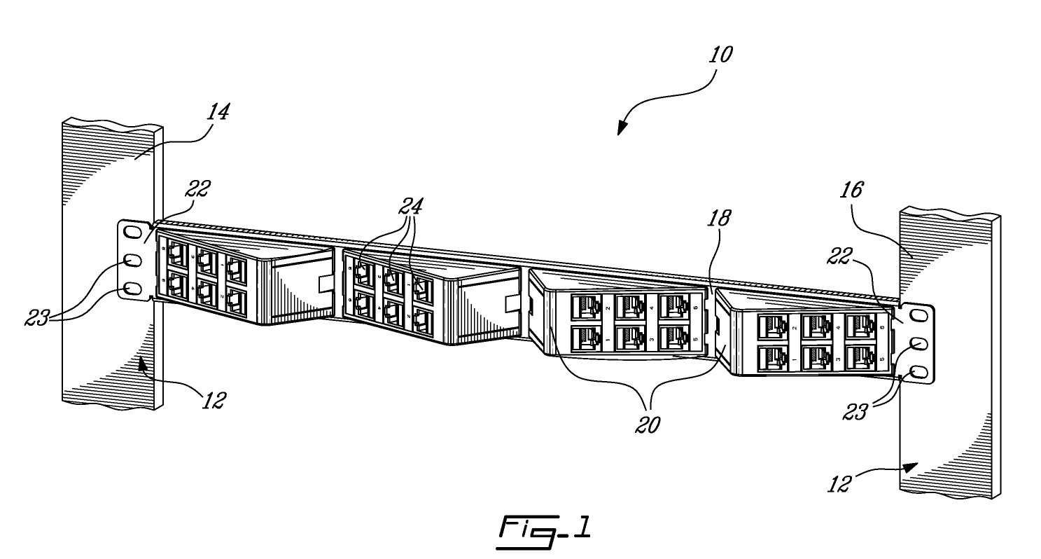

Referring now to FIG. 1, and in accordance with an illustrative embodiment of the present invention, a patch panel with angled modules, generally referred to using the reference numeral 10, will now be described. The patch panel 10 is illustratively mounted to a standard network rack 12 comprising two spaced vertical side rails 14 and 16. The patch panel 10 comprises a frame (not shown) with of a planar and elongate frame member 18 having a plurality of angled connector modules as in 20 mounted thereon. Although the frame has been illustrated as being comprised essentially of the planar frame member 18, other types of frames, such as angled or arcuate frames (none shown), comprising at least one planar frame member 18 to which the angled connector modules as in 20 are mounted may be used without departing from the scope of the present invention. The frame (and according to the present illustrative embodiment, the frame member 18) also comprises at each end thereof a mounting plate 22, in which mounting apertures 23 are formed to allow the frame to be mounted to the rails 14 and 16 through the use of fasteners such as nuts, bolts, and the like (not shown). Each module as in 20 further comprises one or a plurality of linearly aligned connectors as in 24, which are illustratively spaced horizontally, as will be discussed further herein below.

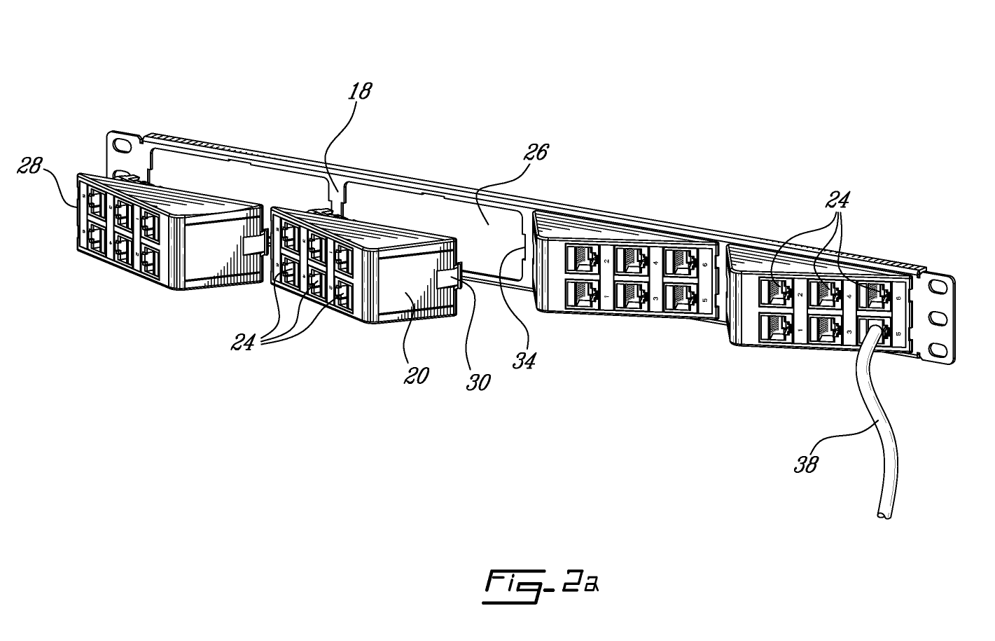

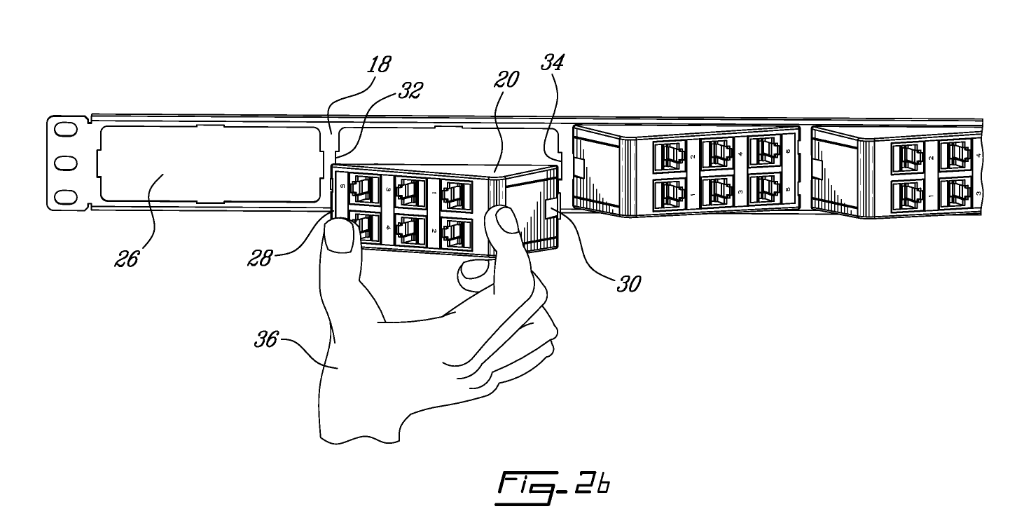

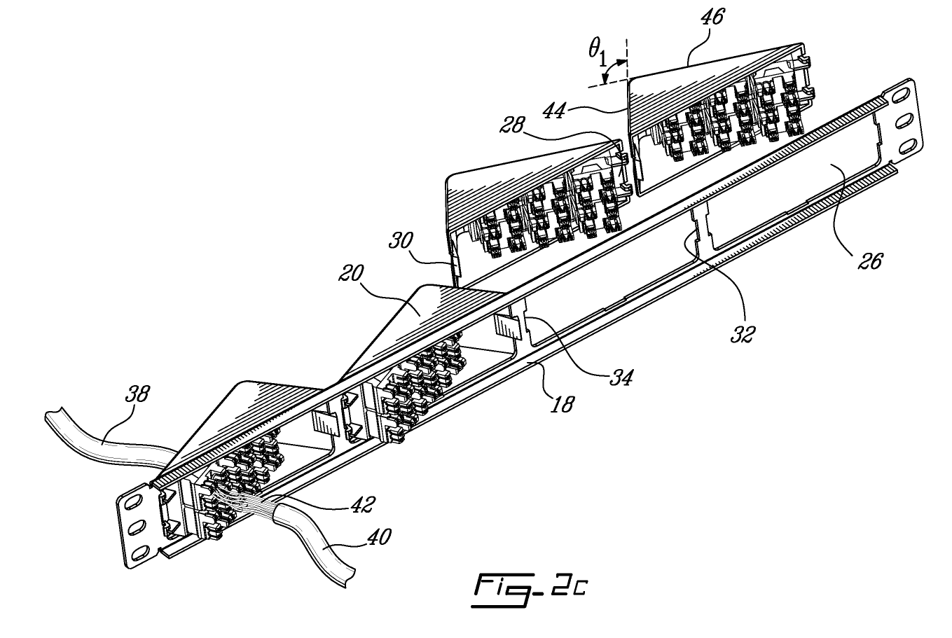

Referring now to FIGS. 2a and 2c in addition to FIG. 1, the frame member 18 illustratively has a plurality of rectangular openings or receptacles as in 26 arranged linearly for receiving the angled connector modules as in 20 therein. Indeed, the connector modules as in 20 are illustratively sized and designed to fit in one of the receptacles as in 26 so that they can be detachably mounted thereon, illustratively in front of the receptacles as in 26. For this purpose, each connector module as in 20 comprises front attachment in the form of a snap latch 28 attached to a first edge thereof and a snap latch 30 attached to a second edge thereof. Each receptacle as in 26 further comprises a first notch 32 and a second notch 34 for receiving, depending on the orientation, the latch 30 therein. The latch 28 is illustratively designed such that, when inserted into a receptacle as in 26, it abuts against the rear face of the frame member 18 to provide a hinging motion to the module 20, as will be discussed further herein below.

Referring now to FIG. 2b in addition to FIG. 2c, during a typical installation, the operator 36 is illustratively able to use a single hand to insert the latch 28 of a connector module 20 behind the edge of the corresponding notch 32 such that the latch 28 abuts against the frame member 18, thus securing a first edge of the module 20 (illustratively the left edge as shown in FIG. 2b) to the frame member 18. To complete the installation, the module 20 is hinged to engage the latch 30 into the notch 34, thus securing the opposite edge of the module 20 (and accordingly the entire module 20) to the frame member 18. The snap-fit design of the connector modules 20 therefore allows for easy installation of the modules 20 into the receptacles 26, thus advantageously alleviating the need for tools and the like. Once the connector module 20 is in place, transmission cables as in 38 may be inserted into the front face of each connector 24 for connection at an opposite rear side thereof to signal transmission cables as in 40 comprising a plurality of individual conductors as in 42, as will be discussed further herein below (FIG. 2c). The receptacles as in 26 are therefore sized to provide sufficient room for the cables to pass through. It is further apparent that the connector module 20 can also be easily removed by pressing on the latch 30 to release it from the notch 34 and subsequently releasing the latch 28 from the notch 32.

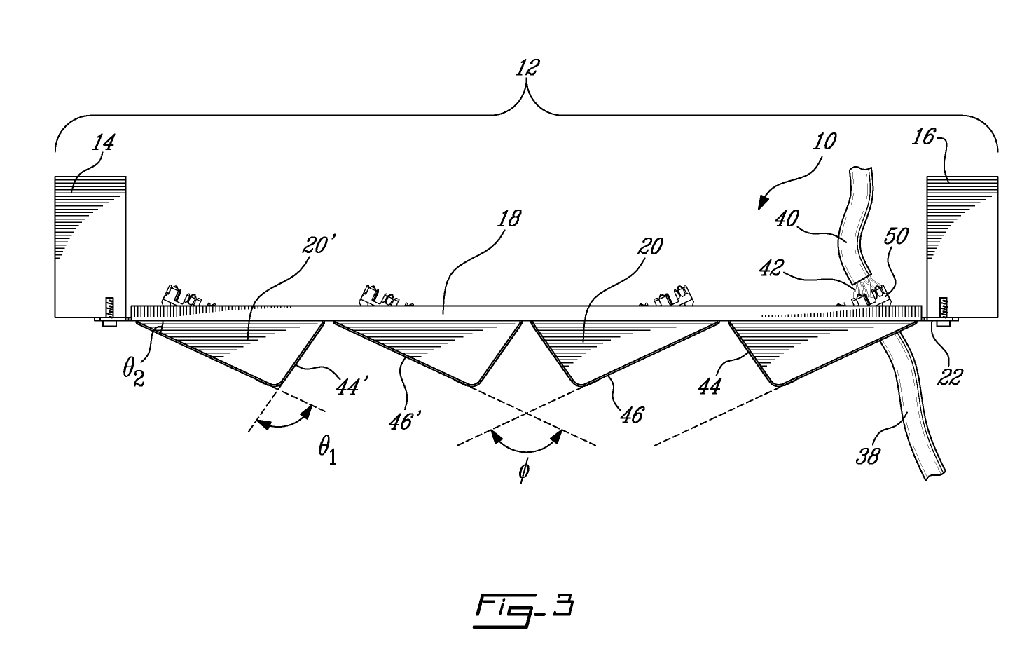

Referring now to FIG. 3, the outer vertical faces 44 and 46 of each connector module 20 are outwardly angled relative to one another to form a generally V-shape having an angle ƒ₁, when viewed from above. The face 46 is then illustratively angled relative to the frame member 18 by an acute angle θ₂. This angular relationship allows for the front surface of each cable connector as in 24 to be better oriented, i.e. at a reduced angle, relative to the exit direction of cables exiting vertical cable managers (not shown), which typically contain cables as in 38 plugged into the patch panel 10. Indeed, conventional flat-faced patch panels are typically oriented substantially parallel to the exit direction of the cables and thus require cable bends of 900 for connection. As a result, an external horizontal cable manager is often required adjacent to the patch panel to control the bends and ensure a minimum bend radius. With angled patch panels, the bend angle required for connection of incoming cabling is less than 90° as the patch panel as in 10 has surfaces, which intersect the vertical rails as in 14 and 16 and thus the exit direction of the cables, at an acute angle. Each cable is therefore routed directly from a frame member 18 to an adjacent vertical cable manager and the need for horizontal cable managers is therefore eliminated. Thus, angling of the patch panel 10 has the advantage of optimizing cable bend radius while easing cable routing to the sides of the rack 12. The outwardly angled modules 20 also allow for enhanced space utilization by providing more surface area on the front face of the modules 20, and accordingly on the front face of the overall patch panel 10, allowing for increased port capacity. The patch panel 10 can therefore withstand high-density cables, resulting in increased functionality. An additional advantage of the angled modules 20 of the present invention is that, when a plurality of frames and frame members as in 18 are mounted to the rails 14 and 16 one on top of the other, the operator is still provided with sufficient space to insert a hand between the stacked modules 20 of two adjacent frames members as in 18, in order to for example add or remove a module as in 20.

Still referring to FIG. 3, it will be apparent to a person skilled in the art that the face 46 of each connector module 20 may be arcuate instead of being flat. In this case, the connectors 24 could illustratively be placed at equiangular positions along this arcuate face. Also, other geometries (e.g. stair-stepped face) could be considered.

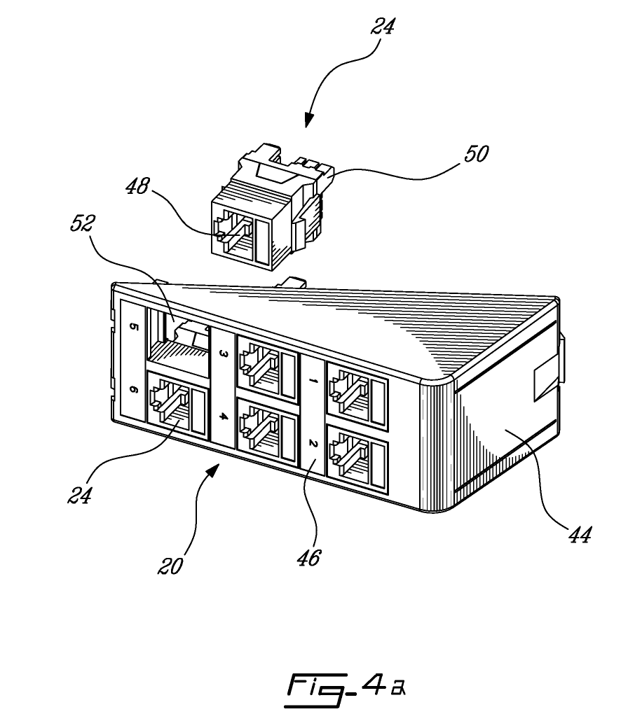

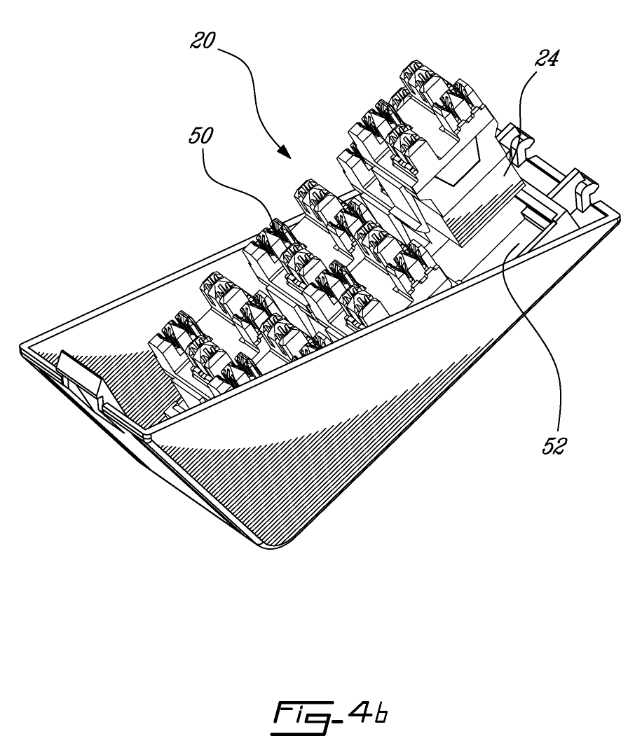

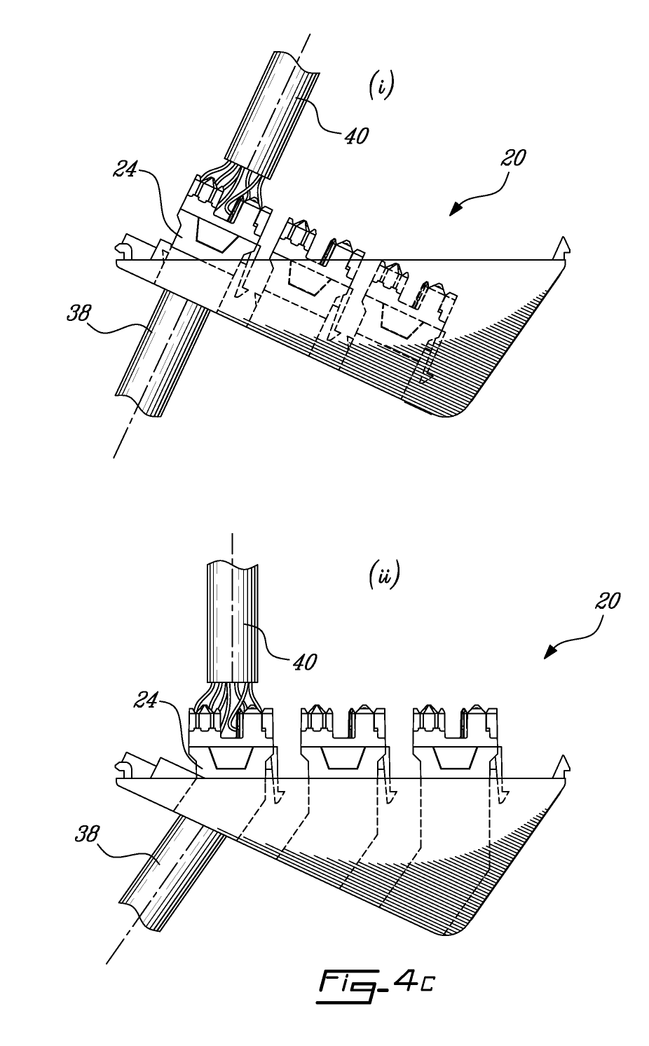

Referring now to FIGS. 4a and 4b, for each connector module 20, illustratively only one of the faces 44 and 46, namely face 46, holds connectors as in 24. Also, each connector module 20 is designed such that the face 46 has a greater dimension than the face 44, thus providing for an increased connector density. The connectors 24 are illustratively of the keystone type and received into openings 52 on the face 46 of the connector modules 20. The openings 52 form a linear array in order to horizontally space a plurality of connectors 24 arranged linearly, thus providing for high-density connections at each module 20. Each connector 24 has a plug receiving receptacle 48 (i.e. a connector jack or port) of conventional design (e.g. RJ45) and appropriate level of performance (e.g. category 5 or 6 cable standard) at a front surface of face 46 and semi permanent connections 50, such as “punch-down” wire termination or connection blocks with Insulation Displacement Conductors (IDCs) associated to the connector jacks 48 on the opposite rear surface of face 46. The termination blocks 50 typically allow for connection to the signal transmission cables 40 containing the individual conductors 42. It should be apparent to a person of skill in the art that the inventive patch panel 10 with angled connector modules 20 herein described may also be used with a variety of other different cable technologies, such as fiber optic cable technology for instance, without departing from the scope of the present invention.

Referring now to FIG. 4c in addition to FIGS. 4a and 4b, the connectors 24 may illustratively be designed such that the connections 50 are substantially perpendicular to the rear of the connector 24 (FIG. 4c (ii)), instead of being angled relative to the latter (as shown in FIG. 4c (i) and illustrated in FIGS. 4a and 4b). Such a configuration advantageously allows for the transmission cables 40 to be terminated flat at the rear of the connector module 20. In this manner, installation is eased and cable bend radius is further controlled, thus improving overall performance.

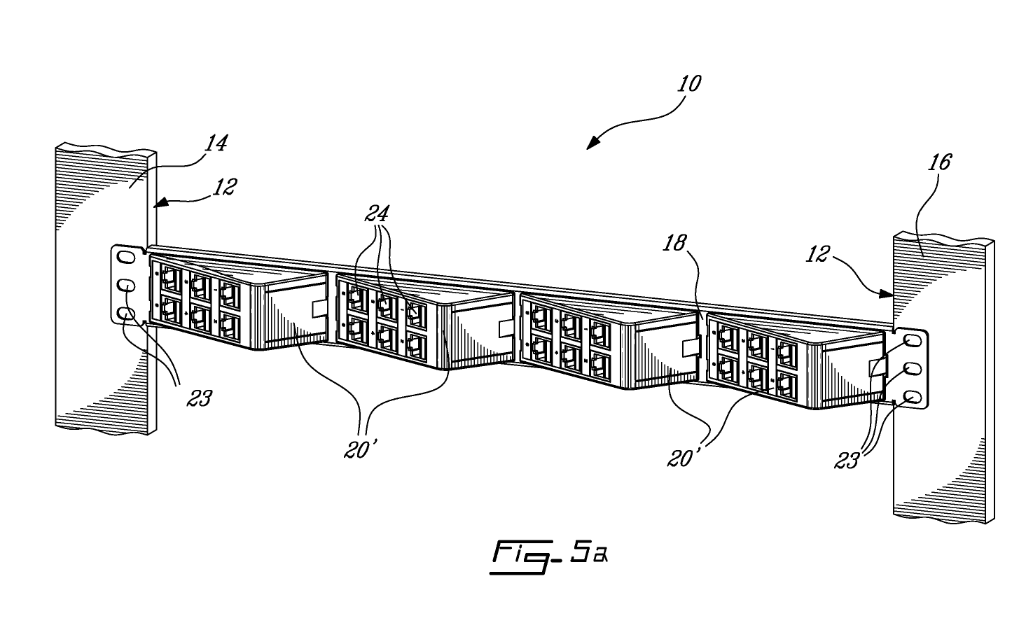

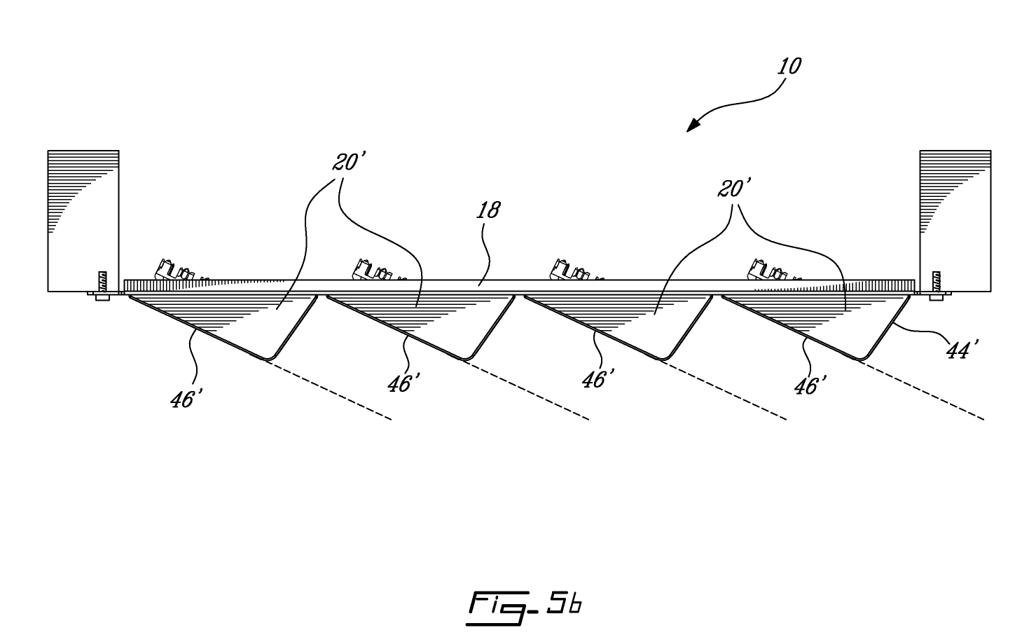

Referring now to FIGS. 5a and 5b, the patch panel 10 of the present invention offers the additional advantage of allowing the left-to-right orientation of the modules 20 to be reversed on the same panel frame member 18. Indeed, the connector modules 20 (and thus the connectors 24 mounted therein) can illustratively be mounted in one of two orientations (with the connector modules 20′ being in reverse orientation relative to the modules 20) relative to the frame member opening (reference 26 in FIG. 1), according to the left or right orientation of the faces 46. Illustratively, a connector module 20 can be oriented in a different direction relative to an adjacent module 20′, with the faces 44′ and 46′ of the modules 20′ having a reversed orientation relative to that of the faces 44 and 46 of the modules 20. In this manner, the patch panel 10 can be mounted such that any two faces 46 and 46′ lie in vertical planes intersecting at an angle φ of degrees (see FIG. 3). Alternatively, the patch panel 10 can be mounted with (some or) all the connectors as in 20′ oriented in the same direction, thus providing for faces 46′, which lie in substantially parallel planes as in FIG. 5b. As a result and as will now be apparent to a person skilled in the art, when mounting a plurality of frames and frame members as in 18 to the rails 14 and 16 one on top of the other, reversing the orientation of the modules 20 allows for a pattern (e.g. staggered modules 20) to be formed between the different panel frames members as in 18 over the length of a network rack as in 12. The reversibility of the modules 20 therefore advantageously allows for the management of cables connected to the patch panel 10 to be improved by tailoring the pattern of the patch panel 10 to a desired application. It will also be apparent to a person skilled in the art that, although the modules 20 have been illustrated as being alike, connector modules as in 20 having different sizes could also be used without departing from the scope of the present invention.

Although the present invention has been described hereinabove by way of specific embodiments thereof, it can be modified, without departing from the spirit and nature of the subject invention as defined in the appended claims.

We claim:

1. A patch panel for mounting to a telecommunications rack comprising a pair of spaced vertical rails, the patch panel comprising:
a frame adapted for attachment between the rails and comprising a substantially flat elongate frame member spanning a first vertical plane and having an opening therein; and
a connector module mounted in front of said elongate frame member to said frame member opening, said module comprising a face spanning a second vertical plane and a plurality of plug receiving receptacles spaced horizontally along a front surface of said face;
wherein said second plane intersects said first plane at a first acute angle and a left-to-right orientation of said module relative to said frame member opening is reversible.

2. The patch panel of claim 1, wherein each of said plurality of plug receiving receptacles is associated with a corresponding plurality of connections arranged along a rear surface of said face, each of said plurality of connections adapted to receive therein a conductor of a cable.

3. The patch panel of claim 2, wherein each of said plurality of connections is an IDC and is arranged substantially perpendicular to said face.

4. The patch panel of claim 1, wherein said frame member has a second opening therein with a second module mounted thereto, said second module comprising a face spanning a third vertical plane intersecting said first plane at said first acute angle and a plurality of plug receiving receptacles spaced horizontally along said face.

5. The patch panel of claim 4, wherein said third plane intersects said second plane at a third angle.

6. The patch panel of claim 4, wherein said third plane is substantially parallel to said second plane.

7. The patch panel of claim 1, wherein said module is releaseably mounted to said frame member.

8. The patch panel of claim 1, further comprising a pair of mounting plates, one of each of said plates at either end of said frame and each of said plates for attachment to a corresponding one of the rails.

9. A connector module for mounting to a patch panel comprising a frame comprising a substantially elongate frame member spanning a first vertical plane, the frame member comprising an opening for receiving the connector module therein, the connector module comprising:
a face spanning a second vertical plane and a plurality of plug receiving receptacles spaced horizontally along a front surface of said face;
wherein when the connector module is mounted in front of the elongate frame member to the frame member opening, said second plane intersects the first plane at a first acute angle and a left-to-right orientation of the module relative to the frame member opening is reversible.

10. The connector module of claim 9, wherein the module comprises front attachment for releaseably mounting the connector module to the frame member opening.

11. The connector module of claim 10, wherein said front attachment comprises latches attached at edges of the module, and further wherein when the module is mounted in front of the frame member to the frame member opening said latches abut against a rear surface of the frame member.

12. The connector module of claim 9, wherein said face is arcuate, and further wherein said second plane is tangential to said arcuate face.

13. The connector module of claim 9, wherein said face is a stair-stepped face comprising a plurality of steps, and further wherein said second plane is tangential to edges of said steps.

14. The connector module of claim 9, wherein each of said plurality of plug receiving receptacles is associated with a corresponding plurality of connections arranged along a rear surface of said face, each of said plurality of connections adapted to receive therein a conductor of a cable.

15. The connector module of claim 14, wherein each of said plurality of connections is an IDC and is substantially perpendicular to said face.

16. The patch panel of claim 9, wherein said plurality of plug receiving receptacles uses fiber optic cable technology.

17. A method for mounting a patch panel to a telecommunications rack comprising a pair of spaced vertical rails, the method comprising:
providing a frame comprising a substantially flat elongate frame member spanning a first vertical plane and having an opening therein;
attaching said frame between the rails;
providing a connector module comprising a face spanning a second vertical plane and a plurality of plug receiving receptacles spaced horizontally along said face; and
mounting said module in front of said elongate frame member to said frame member opening;
wherein said second plane intersects said first plane at a first acute angle and a left-to-right orientation of said module relative to said frame member opening is reversible.

18. The method of claim 17, further comprising providing at a first edge of said module a first latch and a second latch at a second edge of said module opposite to said first edge, wherein said mounting said module in front of said elongate frame member to said frame member opening comprises inserting said first latch within said frame member opening in abutment against a rear surface of said frame member, thereby securing said first edge to said frame member, and subsequently hinging said module to engage said second latch into said frame member opening in abutment against said rear surface, thereby securing said second edge to said frame member.

19. The method of claim 17, further comprising providing a second one of said frame, attaching said second frame to the rails, and reversing said left-to-right orientation of said module of said frame relative to said left-to-right orientation of said module of said second frame, thereby creating a pattern of said modules along a length of the rails.

20. The method of claim 17, further comprising providing a second opening in said frame member, providing a second one of said module comprising a face spanning a third vertical plane and a plurality of plug receiving receptacles spaced horizontally along said face, and mounting said second module in front of said frame member to said second frame member opening, wherein said third plane intersects said first plane at said first acute angle.

21. The method of claim 20, wherein said third plane intersects said second plane at a second angle.

22. The method of claim 20, wherein said third plane is substantially parallel to said second plane.
